(19) United States
(12) Patent Application Publication
(10) Pub. No.: US 2025/0077178 A1
(43) Pub. Date: Mar. 6, 2025

(54) METHOD FOR FEATURING SIGNALS USING ONE-DIMENSIONAL CENTER ASYMMETRIC-SYMMETRIC LOCAL BINARY PATTERNS

(71) Applicant: SAMSUNG ELECTRÔNICA DA AMAZÔNIA LTDA, CAMPINAS (BR)

(72) Inventors: PEDRO GARCIA FREITAS, CAMPINAS (BR); GIOVANI DECICO LUCAFÓ, CAMPINAS (BR); REFAEL GONCALVES LIMA, CAMPINAS (BR); PAULA GABRIELLY RODRIGUES, CAMPINAS (BR); ITALOS ESTILON DA SILVA DE SOUZA, CAMPINAS (BR); ROGERIO SEIJI HIGA, CAMPINAS (BR); THIAGO DE LIMA REZENDE, CAMPINAS (BR); RUAN ROBERT BISPO DOS SANTOS, CAMPINAS (BR); GUSTAVO PESSOA CAIXETA PINTO DA LUZ, CAMPINAS (BR); OTAVIO AUGUSTO BIZETTO PENATTI, CAMPINAS (BR)

(73) Assignee: SAMSUNG ELECTRÔNICA DA AMAZÔNIA LTDA, CAMPINAS (BR)

(21) Appl. No.: 18/490,935

(22) Filed: Oct. 20, 2023

(30) Foreign Application Priority Data
Sep. 6, 2023 (BR) 102023018106 6

(51) Int. Cl. G06F 5/01; H03M 7/24

(52) U.S. Cl. CPC G06F 5/01; H03M 7/24

(57) ABSTRACT

A method for aggregating a center-asymmetric and center-symmetric approaches to produce a center-asymmetric-symmetric (CAS) descriptor to extract features of one-dimensional signals, resulting in a robust and fast technique, which consumes less memory resources for further classification purposes.

### CROSS-REFERENCE TO RELATED APPLICATION(S)

This application is based on and claims priority under 35 U.S.C. § 119 to Brazilian Patent Application No. BR 102023018106-6, filed on Sep. 6, 2023, in the Brazilian Intellectual Property Office, the disclosure of which is incorporated by reference herein in its entirety.

### TECHNICAL FIELD

Photoplethysmography (PPG) is an increasingly widespread optical technique for non-invasive and continuous monitoring of physiological variables from users of consumer electronic devices with restricted memory and processing resources, such as wearables devices.

Therefore, a feature extraction method for a unidimensional PPG signal from a wearable sensor is presented herein, which demonstrates improved on-device execution time. The “Center Asymmetric-Symmetric Local Binary Patterns” (CASLBP) proposed herein, is a modified version of the existing unidimensional version of the “Local Binary Pattern” (LBP) descriptor that achieves similar information discriminability with less parameters, resulting in a lower memory consumption.

The asymmetrical component of the CASLBP descriptor improves the description of the feature extraction.

### BACKGROUND OF THE INVENTION

There is a diversity of methods and models for extracting features to describe relevant attributes of unidimensional signals. Among these methods, the one-dimensional Local Binary Pattern (LBP) descriptor is one of the most advantageous because it presents a high descriptability capacity while requiring few computational resources. The one-dimensional LBP descriptor was employed in a diversity of applications, such as the classification of epileptic Electroencephalography (EEG) signals, heart sounds classification, voice activity detection, noise onset identification, activity detection, etc. Despite the advantage of the LBP descriptor, it has the drawback of the feature vector size increasing in terms of the neighborhood size. This increase is a constraint for problems that require larger numbers of neighbors to describe a phenomenon of interest. In these cases, the one-dimensional LBP fails to generate small-sized features.

The patent document U.S. Pat. No. 9,177,104 B2, entitled “Discriminatively weighted multi-scale local binary patterns”, published on Mar. 26, 2014, by Case Western Reserve University, describes an apparatus and method for prostate cancer detection in magnetic resonance images of the prostate. It employs a machine learning approach based on a set of LBP descriptors extracted from the image at multiple scales. Moreover, this document adopts a salient feature detection logic to detect salient regions in the input image based on a weighted vector and a pixel-by-pixel weighted Hamming matching of the image. The present invention, on the other hand, does not tackle methods for images. On the contrary, the invention discloses a method to extract features from one-dimensional signals.

The patent document U.S. Pat. No. 10,129,495 B2, entitled “Apparatus and method for generating local binary patterns (LBPS)”, published on Nov. 13, 2018, by QUALCOMM INC., describes a technique for direct local binary pattern (LBP) generation. It targets an image sensor for LBP generation that considers two-dimensional inputs. It includes a variable reference signal generator and a sensor pixel array that can generate events based on optical signals on the sensor pixel array and a reference level from the variable reference signal generator. The image sensor may also include a local binary pattern generator configured to determine local binary pattern labels for image pixels whose binary value changes from a first binary image at a first reference level to a subsequent second binary image at a next reference level. The present invention, contrarily, discloses a method to extract features from one-dimensional signals.

The patent document U.S. Pat. No. 10,395,098 B2, entitled “Method of Extracting Feature of Image to Recognize Object”, published on Aug. 27, 2019, by Samsung Electronics Co. Ltd., discloses a method of converting a vector corresponding to an input image into a feature data based on a projection matrix having a fixed rank, wherein a first dimension of the input vector data is higher than a second dimension of the feature data. In short, this patent document discloses a feature extraction method for two-dimensional input signals. In this sense, the present invention also discloses a method for extracting features from signals. However, contrary to U.S. Pat. No. 10,395,098B2, the present invention describes a method to extract features from one-dimensional signals, which represents a more generalizable path under various types of biological signals.

Moreover, although many prior-art methods were proposed to extract features of one-dimensional signals such as ECG, PPG, accelerometer data, etc, in general, they are not adequate in terms of computational complexity and memory consumption. Among the available feature extractors, the one-dimensional LBP descriptor has been used in a diversity of applications. However, in some scenarios, this descriptor cannot be suitable for embedded systems with strong processing and memory constraints.

While the original LBP descriptor has been used in two-dimensional image processing for applications such as texture segmentation and feature detection, the unidimensional LBP was presented and applied for a variety of one-dimensional signal processing applications such as noise onset identification, heart sound classification, etc. In this invention, the proposed CAS-LBP is described to be applied to extract features of physiological signals such as photoplethysmography, electrocardiography, electroencephalography, etc.

### SUMMARY

In this sense, the method proposed herein is able to overcome the problem of extracting and characterizing meaningful information from one-dimensional signals such as Electroencephalogram (EEG), electrogastrogram (EGG), electromyogram (EMG), inertial (i.e., accelerometer and gyroscope), plethysmogram (PTG), electrocardiogram (ECG), photoplethysmogram (PPG), etc., using reduced computational resources, leading to a wide range of signal processing solutions using resource-constrained devices such as smartwatches, fitness trackers and wearable sensors in general. Examples of applications that can benefit from this include signal quality assessment, classification of epileptic EEG signals, change-point detection in temporal series, heart sounds classification, activity recognition, food intake recognition, voice detection, physiological signal biometric identification, fall detection, hand tremor detection and a myriad of other possibilities, not only for wearables, but also for more resourceful devices, such as smartphones and laptops.

Additionally, this invention aggregates the center-asymmetric and center-symmetric strategies to produce a center-asymmetric-symmetric (CAS) descriptor to extract features of one-dimensional signals, resulting in a robust and fast technique, which consumes less memory resources when compared with other techniques in the state of the art.

### BRIEF DESCRIPTION OF THE DRAWINGS

The objectives and advantages of the current invention will become clearer through the following detailed description of the example and non-limitative drawings presented at the end of this document.

FIG. 1 relates to different circularly symmetric neighbor sets as function of radius R and number of neighbors P in an LPB descriptor according to an exemplary embodiment of the present invention.

FIG. 2 presents example of calculation of two-dimensional LBP labels according to an exemplary embodiment of the present invention.

FIG. 3 illustrates a comparison of two-dimensional LBP and CS-LBP operator with 8 neighbors according to an exemplary embodiment of the present invention.

FIG. 4 depicts a segment of sampled one-dimensional signal according to an exemplary embodiment of the present invention.

FIG. 5 depicts different signal sampling strategies adopted by the proposed method according to an exemplary embodiment of the present invention.

FIG. 6 depicts the computing of the proposed center asymmetric-symmetric local binary pattern descriptor according to an exemplary embodiment of the present invention.

FIG. 7 presents a block diagram of a classification system using the proposed CAS-LBP descriptor according to an exemplary embodiment of the present invention.

FIG. 8 illustrates an exemplary embodiment of the CAS-LBP descriptor for modelling a signal quality assessment model according to an exemplary embodiment of the present invention.

FIG. 9 depicts an exemplary embodiment of the CAS-LBP descriptor for activity detection according to an exemplary embodiment of the present invention.

FIG. 10 depicts an example of PPG quality annotation tool interface according to an exemplary embodiment of the present invention.

### DETAILED DESCRIPTION

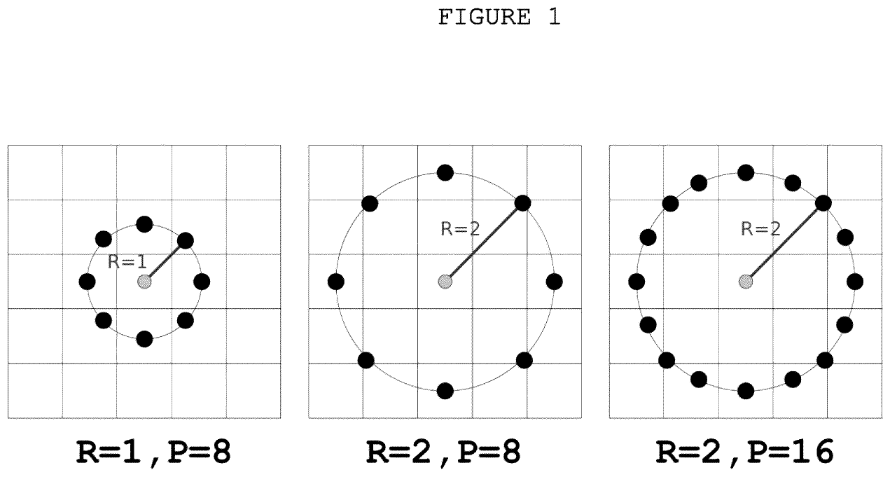

FIG. 1 depicts different circularly symmetric neighbor sets as function of radius and number of neighbors for the first two-dimensional Local Binary Pattern (LPB) descriptor of the state of the art. This LBP descriptor has two main parameters related to sampling, the radius (R) and the number or neighboring pixels (P). FIG. 1 illustrates examples of symmetric samplings with different numbers of P and R values. Once the P and R parameters have been defined, the LBP descriptor can be computed using the following mathematical formulation:

$${LBP}_{R , P} ( {I}_{c} ) = {\sum }_{p = 0}^{P - 1} S ( {I}_{p} - {I}_{c} ) {2}^{p} \\ where S ( t ) = \{ \begin{matrix}0 , & t < 0 \\ 1 , & t \geq 0\end{matrix}$$

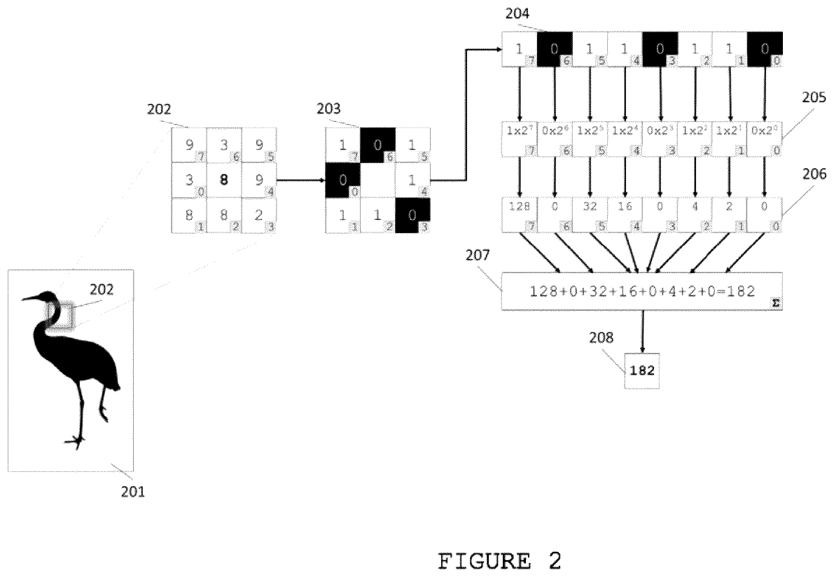

In the above equation, I_{c}=I(x, y) is a random central pixel at the position (x, y) of the image and Iₚ=I(xₚ, yₚ) is the p^{th} neighboring pixel surrounding I_{c} respecting the constrained by the parameters P and R. In this case, xₚ=x+R cos 2πp/P and yₚ=y−R sin 2πp/P. An example for labeling pixels with the LBP operator is given in FIG. 2 when the LBP descriptor has P=8 and R=1 as parameters. In this figure, some pixels are sampled from the image (201) and form a block (202) with a central pixel I_{c}=8 located in the center of a 3×3 block 202. The numbers in the gray squares of block 202 represent the order in which the descriptor is computed (counter-clockwise direction starting from 0). After calculating S(t) for each neighboring pixel Iₚ s.t. 0≤p≤7, the binary output for each lₚ, as illustrated in 203. These binary outputs are stored in a binary format, according to their position (i.e., the gray squares) as illustrated in 204. For each entry in this string of binary values the Base-2 (205) representation is converted to the equivalent Base-10 (206) and then generates the decimal representation (207) that corresponds to the corresponding LBP label (208). After these steps are applied to all pixels of the image, a histogram of all LBP labels can be used as a feature to characterize the whole image 201 since it may provide descriptive statistics about its visual information.

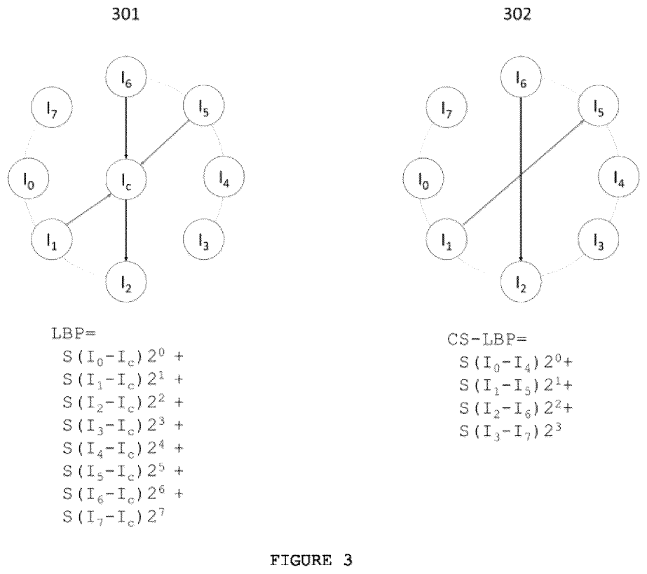

FIG. 3 shows an example of obtaining the two-dimensional LBP and a center-symmetric LPB (CS-LBP) with eight neighbors around I_{c}. It can be noticed that LBP operator produces rather long histograms and is therefore difficult to use in the context of a region descriptor. From 301, for 8 neighbors, LBP produces 256 different binary patterns. On the other hand, to produce more compact binary patterns, the center-symmetric LBP at 302 generates only 16 different binary patterns. CS-LBP operator is an effective extension to LBP by shortening the feature length considerably. However, different from LBP, which compares each neighbor with the central pixel, it compares the grey values of pairs of pixels in center symmetric direction:

$$CS - {LBP}_{R , P} ( {I}_{c} ) = {\sum }_{p = 0}^{P / 2 - 1} S ( {I}_{p} - {I}_{p + P / 2} ) {2}^{p}$$

where Iₚ and Iₚ₊P/2 are the values of neighborhoods pixels in the center-symmetric direction. Specifically, Iₚ and Iₚ₊P/2 correspond to center-symmetric pairs of pixels of P equally spaced pixels on a circle of radius R.

Given this brief overview of the state-of-the-art known techniques, the following excerpts of the application are related to the featuring of signals using one-dimensional center asymmetric-symmetric local binary patterns (CAS-LBP).

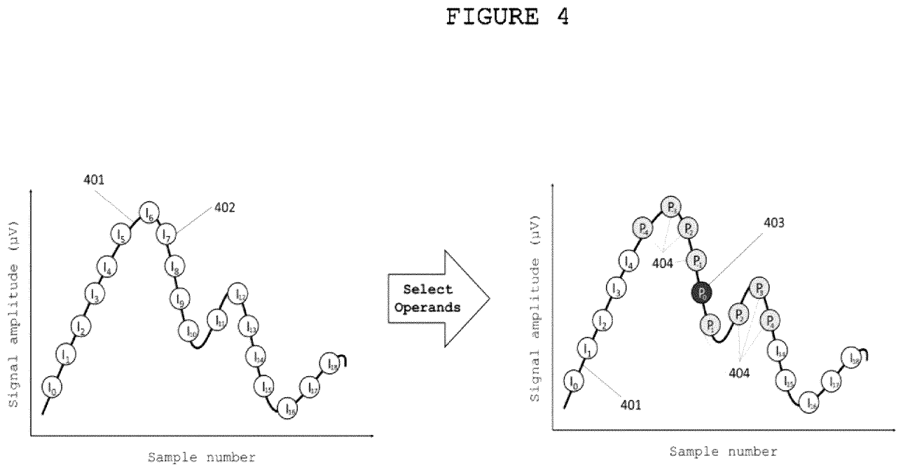

FIG. 4 illustrates a sample segment of a 1D signal. Considering a signal (401) comprised of samples (402), the CAS-LBP operates as an ordered set of comparisons between the center value (403) and its neighborhood (404). Since the center value divides the neighboring sampling into two subsets of neighbors—right and left neighbors—, it is possible to define different sampling strategies to create these neighborhoods.

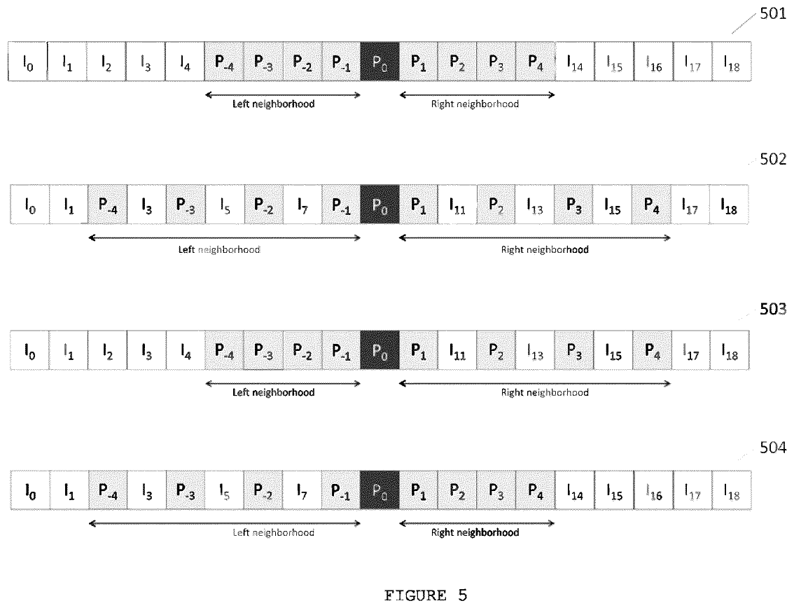

FIG. 5 illustrates some possible sampling strategies. In the most naïve approach, both right and left neighborhoods are taken from the first samples before and after the central sample (501). Nevertheless, alternative sampling orders can be performed depending on the problem to be modeled. One of these alternatives is to increase the spacing between neighbors (502), which is equivalent to locally subsampling the signal to calculate the descriptor. When the left and right neighbors are equally sampled as depicted in 501 and 502, it is defined as ‘symmetric’. On the other hand, in the case of different configurations for the right and left sides (503) and (504), it is defined as ‘asymmetric’.

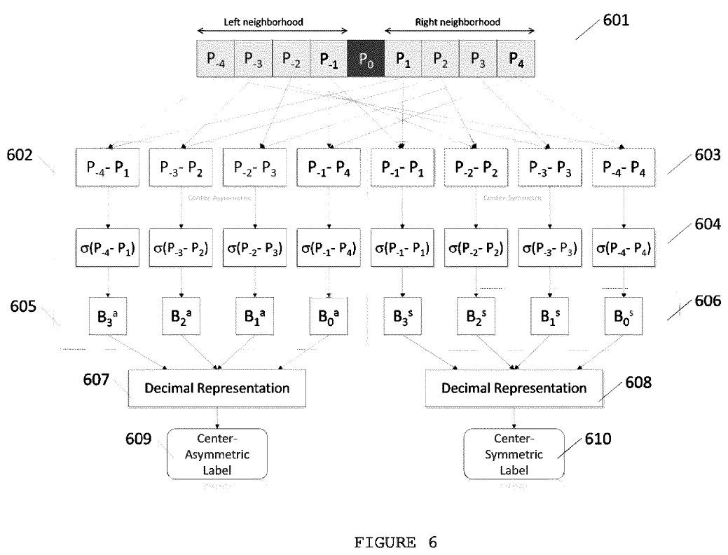

Considering the neighborhoods sampling according to one of the strategies illustrated in FIG. 5, the CAS-LBP descriptor is computed as illustrated in FIG. 6. For each sample of the signal, the left and right neighboring samples are considered as before (P₋₄, P₋₃, P₋₂, and P₋₁) and after (P₁, P₂, P₃, and P₄) the center sample P₀, respectively (601). As show in 602, values of all left neighboring samples are subtracted from the opposite counterpart (i.e., P₋₄−P₁, P₋₃−P₂, and so on), in center-asymmetric way. Similarly, the same left and right samples are then subtracted a center-symmetric order as considering illustrated in 603. These subtractions are binarized according to the thresholding function s (604) defined as

$$σ ( x ) = \{ \begin{matrix}1 , & x < 0 \\ 0 , & otherwise\end{matrix} .$$

As in 605, neighboring sample differences are limited to produce a binary number s (Pᵢ−P_{i-N}), where N=8 is the number of left/right neighbors. For each difference, if this difference is lower than zero, the corresponding value is taken as 1 otherwise 0. Thus, a binary code Bia is formed for a neighborhood. Similarly, the binarized differences of the center-symmetrically samples form a binary code of Bis (606). The decimal value of this binary code represents the local structural information around the given P₀. In this way, the decimal representation (607) of the asymmetric binary pattern 605 corresponds to a center-asymmetric label (609). In a similar manner, the center-symmetric binary patterns (606) are converted to a decimal representation (608) to produce a center-symmetric label (610).

The stages illustrated in FIGS. 3, 4 and 6 are performed for all samples of the signal vector. By adopting this procedure, a list of labels is produced by each center-asymmetric and center-symmetric case. Each of these label cases has values ranging from 0 to 22, where N is the number of neighbors and each one corresponds to a different pattern. Therefore, by using each pattern as a unique label with a corresponding histogram bin, a center-asymmetric histogram and a center-symmetric histogram can be constructed from the statistics of these labels. When the histogram of the obtained labels is produced, it shows how often each of these 22 different patterns appear in a given signal. These histograms are used as features for modeling classification problems.

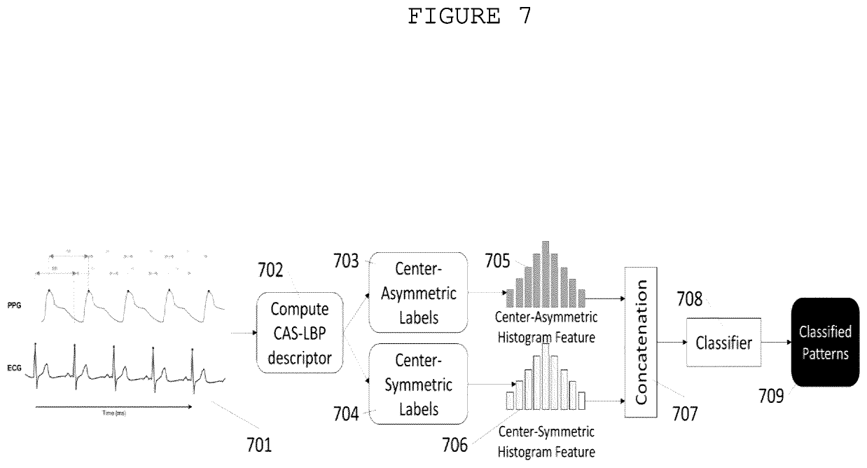

FIG. 7 illustrates a block diagram of a generic classification system using the CAS-LBP descriptor as a feature extractor of one-dimensional signals. One or more signals (701) obtained via the sensor are sampled to be used as input to the proposed CAS-LBP descriptor (702). FIG. 7 presents ECG and PPG signals as example in 701. Other types of signals and temporal series can also be used, for instance, inertial signals (accelerometer, gyroscopes and magnetometers), sound signals, electroencephalograms, etc. As previously detailed and illustrated in FIG. 6, the input (701) in the classification system is the signal in the time domain and the output is in CAS-LBP (702) domain. This domain transformation produces two sets of labels, i.e., one containing center-asymmetric labels (703) and the other containing center-symmetric labels (704). Each of these sets produces a corresponding histogram, namely a center-asymmetric (705) and center-symmetric (706) histogram. When these histograms are concatenated (707), they produce a feature vector that can be used as input in a classifier model (708). Instances of this classifier model may include a wide variety of algorithms, for instance, Support Vector Machine, Perceptron, Artificial Neural Networks, Decision Trees, Kernel Estimations, Naïve Bayes, etc.

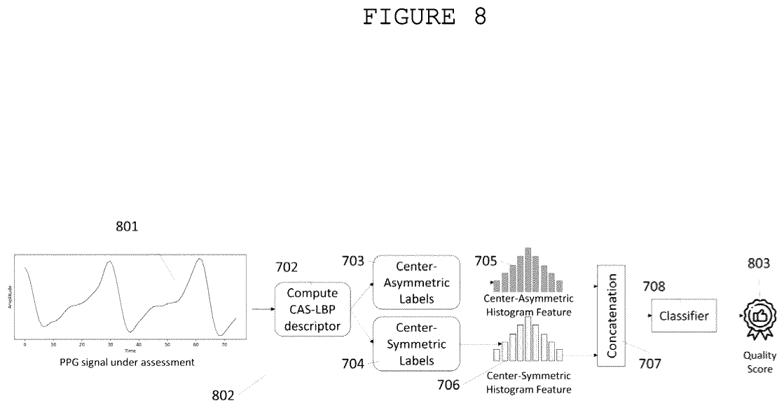

This result can be used in a very wide range of applications. FIG. 8 illustrates how the proposed descriptor can be used directly to model a signal quality classifier to assess whether a signal is good or not. The signal quality classifier is a fundamental task in many health-related applications because poor signal quality due to motion and other types of noise may deteriorate the quality of several physiological estimations, such as the inter-beat interval. To discard potentially unreliable estimations, a method for detecting the quality of the signal becomes crucial.

For this purpose, FIG. 8 depicts a pipeline for classifying a signal segment according to the signal morphology (801). The classifier is trained using human-based photoplethysmography annotations labeled according to the majority vote of the visual inspections performed by a set of specialists. Using this labeled signal data, a classification algorithm is used to estimate the quality. In quality assessment methodologies, regression models are often used to adjust the quality scores provided by the different quality datasets. In the specific case of bio-signals, a common approach is to model quality assessment as a classification problem. To achieve this aim, the complete pipeline of this invention (802) can be used to model a binary classification problem. As an effect, the utilization of the proposed CAS-LBP descriptor produces a pair of individual features, i.e., the center-symmetric histogram feature (705) and the center-asymmetric histogram feature (706). These histogram features are concatenated (707) and inserted as input in a classifier algorithm (708) that generates a quality-related score as output (803). This output assumes a positive binary value whether the PPG signal under assessment is good (e.g., ‘reliable’, ‘decent’, ‘safe’, etc.) or a negative value if it is bad (e.g., ‘unreliable’, ‘unsafe’, etc.).

In summary, the method for featuring signals using one-dimensional center asymmetric-symmetric local binary patterns comprises the steps of:
receiving a set of one-dimensional signal including a set of samples;
wherein for each one-dimensional signal:
defining a central sample P0 and its left neighborhood samples (P_{-N}, . . . , P₋₃, P₋₂, and P₋₁) and right neighborhood samples (P₁, P₂, P₃, . . . , P_{N});
using a center-symmetric approach to select and pair opposing counterpart left and right neighborhood samples;
using a center-asymmetric approach to select and pair left and right neighborhood samples;
wherein paired samples are subtracted and binarized by a thresholding function to produce a set of center-symmetric binary patterns (Bis) and a set of center asymmetric (Bia):

$$σ ( x ) = \{ \begin{matrix}1 , & x < 0 \\ 0 , & otherwise\end{matrix} ;$$

converting the set of center-symmetric binary patterns (Bis) into a decimal representation to produce a center-symmetric label;
converting the set of center-asymmetric binary patterns (Bia) into a decimal representation to produce a center-asymmetric label;
generating a center-asymmetric histogram feature by means of the center-asymmetric label;
generating a center-symmetric histogram feature by means of the center-symmetric label; and
concatenating both center-asymmetric and center-symmetric histogram features and normalizing them in a feature vector

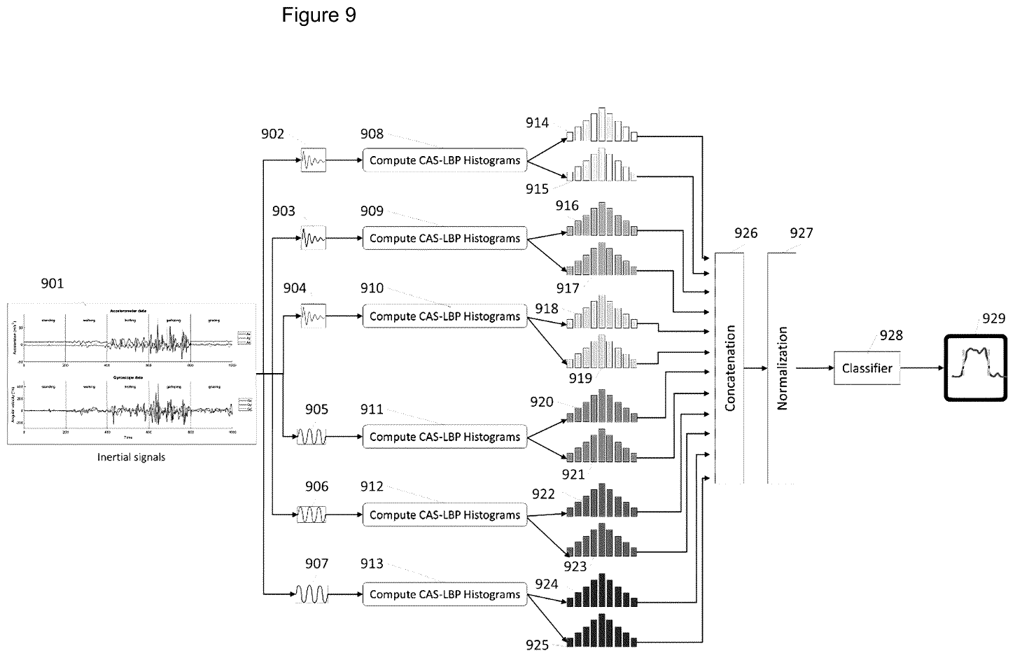

Many alternative embodiments and applications can be derived from the proposed method. FIG. 9 shows an embodiment in which the proposed CAS-LBP operator is used to model an activity detection system. While the first embodiment, depicted in FIG. 8, applies the CAS-LBP to extract features from photoplethysmogram signals for quality assessment purposes, FIG. 9 employs the CAS-LBP descriptor to extract features from accelerometer and gyroscope signals.

A bank of inertial signals (901) created using gyroscope and accelerometer devices is created. The accelerometer signal components are decomposed according to the dimension, i.e., a one-dimensional signal is created from the x-axis accelerometer component (902), another one-dimensional signal is created from the y-axis accelerometer component (903) and another one is created for the z-axis of the accelerometer (904). Similarly, a triple of one-dimensional signals is created for the x-(905), y-(906) and z-axis (907) of the gyroscope data. For each one of these components, the CAS-LBP descriptor, proposed in this invention, is used to compute the histograms of the x (908), y (909) and z (910) components of the accelerometer signal. Similarly, the CAS-LBP descriptor is also used to compute the histograms related to the x (911), y (912) and z (913) components of the gyroscope signal. As an effect, the utilization of the proposed CAS-LBP descriptor produces a pair of individual features for each input signal, i.e., center-symmetric histogram feature (914, 916, 918, 920, 922 and 924) and a center-asymmetric histogram feature (915, 917, 919, 921, 923 and 925) for the components of accelerometer and gyroscope signals. The concatenation of all these center-symmetric and center-asymmetric features (926) produces the feature vector that describes the statistics of every component of each signal. For convenience and to improve the performance and training stability of the model, the feature vector is normalized (927) before being used as input in a classifier algorithm (928). This classifier, finally, is then used to assign a class label corresponding to the recognized activity (929).

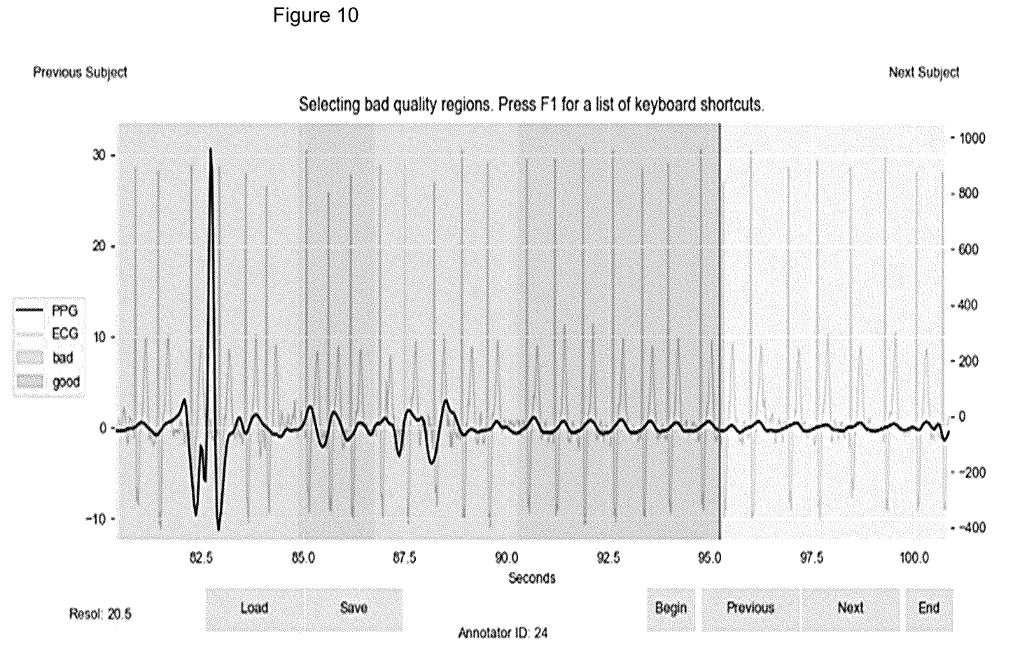

As proof of concept (PoC), the first embodiment illustrated in FIG. 8 was implemented. To validate this PoC, a dataset comprising 56 subjects was used. This dataset contains data from PPG collected with a sampling rate of 25 Hz lasting 45-60 minutes per subject, which required manual annotation by experts for generating the signal quality labels. The process of quality annotation can be performed using an annotation tool such as depicted in FIG. 10.

FIG. 10 shows that some PPG signal segments present irregular and unexpected waveforms. It occurs because of the susceptibility to the noise of PPG sensors, particularly caused by motion artifacts that conceal or even distort information within the signal, leading to incorrect health status prediction, misdiagnosis and other monitoring problems. The occurrence of noisy signal portions is the main motivation for the development of quality assessment methods, since it is crucial to prevent misinterpretation by distinguishing reliable and unreliable physiological signals.

The PoC automatically assesses the quality of PPG signal segments. It operates by receiving a bunch of windows formed by PPG samples as input and, for each window, returning its quality as ‘good’ or ‘bad’. More specifically, the PPG signals are split into windows of 3 seconds in length, corresponding to 75 samples each with an overlap of 5 samples. The PPG segments are normalized via min-max normalization within the interval [0, 1]. To prepare for the learning phase of the model, each segment is labeled according to an arbitrary threshold d, which indicates the fraction of samples annotated as good quality within each segment. If the fraction of samples from human-based annotations classified as good quality is higher than d, then the segment is labeled as “good”. Otherwise, if the portion of samples human-based annotated as “good” is smaller than d, this segment is labeled as “poor”. The set of prepared windows and the corresponding segment labels feed the machine learning model M in the training stage. In particular, d=0.8 was adopted to generate these labels in the experiments.

| | | | | Balanced | | | | | | | | | | | |
|---|---|---|---|---|---|---|---|---|---|---|---|---|---|---|---|
| | Accuracy | | | Accuracy | | | ROC AUC | | | F1 Score | | | Time Taken | | |
| | | CAS- | | | CAS- | | | CAS- | | | CAS- | | | CAS- | |
| Model | LBP | LBP | Δ | LBP | LBP | Δ | LBP | LBP | Δ | LBP | LBP | Δ | LBP | LBP | ρ |
| LGBMClassifier | 0.91 | 0.91 | 0.00 | 0.88 | 0.88 | 0.00 | 0.88 | 0.88 | 0.00 | 0.91 | 0.91 | 0.00 | 23.90 | 3.08 | 7.76 |
| XGBClassifier | 0.91 | 0.91 | 0.00 | 0.88 | 0.88 | 0.00 | 0.88 | 0.88 | 0.00 | 0.90 | 0.90 | 0.00 | 207.94 | 16.88 | 12.32 |
| RandomForest | 0.90 | 0.90 | 0.00 | 0.88 | 0.88 | 0.00 | 0.88 | 0.88 | 0.00 | 0.90 | 0.90 | 0.00 | 502.60 | 129.44 | 3.88 |
| Classifier | | | | | | | | | | | | | | | |
| ExtraTreesClassifier | 0.90 | 0.90 | 0.00 | 0.87 | 0.88 | 0.01 | 0.87 | 0.88 | 0.01 | 0.90 | 0.90 | 0.00 | 832.98 | 179.18 | 4.65 |
| LogisticRegression | 0.90 | 0.90 | 0.00 | 0.87 | 0.87 | 0.00 | 0.87 | 0.87 | 0.00 | 0.90 | 0.90 | 0.00 | 53.74 | 7.83 | 6.86 |
| BaggingClassifier | 0.89 | 0.89 | 0.00 | 0.87 | 0.87 | 0.00 | 0.87 | 0.87 | 0.00 | 0.89 | 0.89 | 0.00 | 499.54 | 74.11 | 6.74 |
| AdaBoostClassifier | 0.90 | 0.90 | 0.00 | 0.87 | 0.87 | 0.00 | 0.87 | 0.87 | 0.00 | 0.90 | 0.90 | 0.00 | 415.48 | 52.83 | 7.86 |
| SGDClassifier | 0.90 | 0.90 | 0.00 | 0.87 | 0.86 | −0.01 | 0.87 | 0.86 | −0.01 | 0.90 | 0.90 | 0.00 | 60.86 | 3.84 | 15.85 |
| LinearDiscriminant | 0.90 | 0.89 | −0.01 | 0.86 | 0.85 | −0.01 | 0.86 | 0.85 | −0.01 | 0.89 | 0.89 | 0.00 | 394.60 | 6.07 | 65.01 |
| Analysis | | | | | | | | | | | | | | | |
| LinearSVC | 0.89 | 0.90 | 0.01 | 0.85 | 0.87 | 0.02 | 0.85 | 0.87 | 0.02 | 0.89 | 0.90 | −0.01 | 1245.72 | 392.26 | 3.18 |
| RidgeClassifier | 0.89 | 0.89 | 0.00 | 0.85 | 0.85 | 0.00 | 0.85 | 0.85 | 0.00 | 0.89 | 0.89 | 0.00 | 27.03 | 1.89 | 14.30 |
| RidgeClassifierCV | 0.89 | 0.89 | 0.00 | 0.85 | 0.85 | 0.00 | 0.85 | 0.85 | 0.00 | 0.89 | 0.89 | 0.00 | 77.01 | 3.21 | 23.99 |
| BernoulliNB | 0.87 | 0.86 | −0.01 | 0.84 | 0.84 | 0.00 | 0.84 | 0.84 | 0.00 | 0.87 | 0.86 | 0.01 | 24.11 | 1.78 | 13.54 |
| NearestCentroid | 0.86 | 0.86 | 0.00 | 0.83 | 0.83 | 0.00 | 0.83 | 0.83 | 0.00 | 0.86 | 0.86 | 0.00 | 24.57 | 1.54 | 15.95 |
| PassiveAggressive | 0.86 | 0.89 | 0.03 | 0.83 | 0.86 | 0.03 | 0.83 | 0.86 | 0.03 | 0.85 | 0.88 | −0.03 | 37.52 | 2.56 | 14.66 |
| Classifier | | | | | | | | | | | | | | | |
| DecisionTree | 0.84 | 0.84 | 0.00 | 0.82 | 0.82 | 0.00 | 0.82 | 0.82 | 0.00 | 0.84 | 0.84 | 0.00 | 95.62 | 13.51 | 7.08 |
| Classifier | | | | | | | | | | | | | | | |
| Perceptron | 0.83 | 0.88 | 0.05 | 0.80 | 0.86 | 0.06 | 0.80 | 0.86 | 0.06 | 0.83 | 0.88 | −0.05 | 28.38 | 2.22 | 12.78 |
| ExtraTreeClassifier | 0.82 | 0.85 | 0.03 | 0.79 | 0.82 | 0.03 | 0.79 | 0.82 | 0.03 | 0.82 | 0.84 | −0.02 | 29.17 | 3.34 | 8.73 |
| Quadratic | 0.77 | 0.83 | 0.06 | 0.66 | 0.76 | 0.10 | 0.66 | 0.76 | 0.10 | 0.73 | 0.82 | −0.09 | 78.18 | 3.93 | 19.89 |
| Discriminant | | | | | | | | | | | | | | | |
| Analysis | | | | | | | | | | | | | | | |
| GaussianNB | 0.73 | 0.85 | 0.12 | 0.60 | 0.79 | 0.19 | 0.60 | 0.79 | 0.19 | 0.67 | 0.84 | −0.17 | 60.61 | 1.77 | 34.24 |
| DummyClassifier | 0.67 | 0.67 | 0.00 | 0.50 | 0.50 | 0.00 | 0.50 | 0.50 | 0.00 | 0.53 | 0.53 | 0.00 | 20.38 | 1.43 | 14.25 |

Table 1 depicts the performance of the proposed CAS-LBP descriptor in comparison with the existing 1D LBP descriptor. The results of this comparison were generated using 4 left and 4 right neighbors. In this table, D represents the difference between the CAS-LBP and LBP. For the best-performing classification models (i.e., LGBMClassifier, XGBClassifier, RandomForestClassifier, etc.), both descriptors perform very similarly. However, by considering the time taken (in seconds) to train and test these models using the analyzed descriptors, the difference is noticeable.

In order to examine the differences between the time taken by both descriptors, the

$$ρ = \frac{time taken by LBP}{time taken by CAS - LBP}$$

is defined to measure how many times the proposed CAS-LBP is faster than the state-of-the-art 1D LBP descriptor. By taking the performance columns (accuracy, balanced accuracy, ROC AUC and F1-Score) and the r column into consideration, it is noticeable that the CAS-LBP descriptor performs remarkably faster than the existing state-of-the-art. For instance, to achieve an accuracy of the same 91% using the LGBMClassifier and XGBClassifiers, the CAS-LBP descriptor performed, respectively, 7.76× and 12.32× faster. Moreover, even for classifier algorithms in which the performance of CAS-LBP is slightly worse, such as LinearDiscriminantAnalysis, QuadraticDiscriminantAnalysis and GaussianNB, the observed improvement in speed is considerable, which is, respectively, 65, 19 and 34 times faster.

This results from the fact that the proposed CAS-LBP descriptor requires less memory to operate and produces smaller feature vectors. For instance, for a left neighborhood of N/2 and a right neighborhood of N/2 neighbors, the ordinary LBP descriptor produces a histogram of 2^{N} bins. On the other hand, for the same number of neighbors, the CAS-LBP descriptor produces a histogram of only

$${2}^{\frac{N}{2} + 1}$$

to be used as a feature vector. Therefore, for N=8, the LBP will produce a histogram of 2⁸=256 bins while the CAS-LBP descriptor produces

$${2}^{\frac{8}{2} + 1} = 32$$

bins. This improvement accelerates the performance of the classifier algorithms as fewer operations are required to solve a smaller dimensionality optimization problem. Moreover, from hardware perspective, the reduced number of operands enables them to be kept in the CPU register, optimizing the use of memory cache and avoiding memory access overheads. Consequently, significantly less energy is used for operation.

Given these advantages, the proposed method brings significant competitive advantages for devices that need high prediction performance, have computational resources constraints and need also need to save considerable amount of energy for a continuous and regular operation.

As a further example, considering the case of a fall detection system to assist smartphone insurance companies, sensor data from both accelerometer and gyroscope could be used to infer if the device has fallen and broken due to reckless/intentional behavior of the owner, or if it was indeed an accident.

The preprocessed segments of accelerometer and gyroscope data, each corresponding to a 1-D time series, could be used as an input to a time series classifier from which an initial step would consist of a CASLBP-based feature extractor. This would reduce the complexity of the input encoding while preserving texture information.

Although the present invention has been described in connection with certain preferred embodiments, it should be understood that it is not intended to limit the disclosure to those particular embodiments. Rather, it is intended to cover all alternatives, modifications and equivalents possible within the spirit and scope of the disclosure as defined by the appended claims.

What is claimed is:

1. A method of featuring signals using one-dimensional center asymmetric-symmetric local binary patterns, comprising:
receiving a set of one-dimensional signal including a set of samples;
wherein for each one-dimensional signal:
defining a central sample P0 and left neighborhood samples (P_{-N}, . . . , P₋₃, P₋₂, and P₋₁) and right neighborhood samples (P₁, P₂, P₃, . . . , P_{N}) of the central sample P0;
using a center-symmetric approach to select and pair opposing counterpart left neighborhood samples and right neighborhood samples;
using a center-asymmetric approach to select and pair the left neighborhood samples and the right neighborhood samples;
wherein paired samples are subtracted and binarized by a thresholding function to produce a set of center-symmetric binary patterns (Bis) and a set of center asymmetric (Bia):
$$σ ( x ) = \{ \begin{matrix}1 , & x < 0 \\ 0 , & otherwise\end{matrix} ;$$
converting the set of center-symmetric binary patterns (Bis) into a decimal representation to produce a center-symmetric label;
converting the set of center-asymmetric binary patterns (Bia) into a decimal representation to produce a center-asymmetric label;
generating a center-asymmetric histogram feature by means of the center-asymmetric label;
generating a center-symmetric histogram feature by means of the center-symmetric label; and
concatenating both the center-asymmetric histogram feature and the center-symmetric histogram feature and normalizing in a feature vector.

2. The method as in claim 1, wherein input samples are subject to an additional preprocessing composed of either Non adaptive filtering including Butterworth, Chebyshev, Elliptical or adaptive filtering including Recursive Least Squares or Least Mean Squares).

3. The method as in claim 1, wherein the feature vector is useable as input in a classifier model.

4. The method as in claim 1, wherein input samples are subject to an additional upsampling or downsampling preprocessing or post-processing.
